(19) United States
(12) Patent Application Publication
(10) Pub. No.: US 2006/0267576 A1
(43) Pub. Date: Nov. 30, 2006

(54) Battery protection method and battery protection circuit

(76) Inventors: Kazuhiro Ooshita, Atsugi-Shi (JP); Takashi Hiroshima, Atsugi-Shi (JP); Itsuki Nakano, Atsugi-Shi (JP)

Correspondence Address: Richard P. Berg, Esq.;c/o LADAS & PARRY, Suite 2100, 5670 Wilshire Boulevard, Los Angeles, CA, 90036-5679, US

(21) Appl. No.: 11/343,934

(22) Filed: Jan. 31, 2006

(30) Foreign Application Priority Data
May 27, 2005 (JP) 2005-156375

(51) Int. Cl. G01R 11/32

(52) U.S. Cl. 324/134

(57) ABSTRACT

A battery protection method is disclosed for protecting a battery from an over-discharge state by switching off a switching element provided between the battery and a load in accordance with the voltage of the battery. The method includes the steps of detecting application of a charging voltage and arranging a chargeable state for the battery by switching on the switching element when the application of the charging voltage is detected.

### BACKGROUND OF THE INVENTION

1. Field of the Invention

The present invention generally relates to a battery protection method and a battery protection circuit, and more particularly to a battery protection method and a battery protection circuit for protecting a battery from over-discharge by switching off a switching element provided between the battery and a load in accordance with the voltage of the battery.

2. Description of the Related Art

Mobile phones are provided with a battery pack which serves as their electric drive source.

The battery pack includes a battery and a protection IC. The battery includes a lithium ion battery having an electric chargable/dischargable configuration. The protection IC disconnects the battery from a load or a charger upon detecting overcharge, over-discharge, or overcurrent of the battery (for example, see Japanese Laid-Open Patent Application No. 11-68527).

FIG. 5 is a block diagram showing an example of a conventional battery pack.

In FIG. 5, a battery pack 1 includes a battery 11, a discharge control transistor 12, a charge control transistor 13, a protection IC 14, resistancors R1, R2, and a capacitor C1. The battery pack 11 is connected to a load 2 or a charger 3.

The battery 11 is, for example, a lithium ion battery having an electric chargable/dischargable configuration. In the battery 11, the positive electrode is connected to a terminal T1 and the negative electrode is connected to the source of the discharge control transistor 12.

The discharge control transistor 12 includes an n channel MOS field-effect transistor. In the discharge control transistor 12, its source is connected to the negative electrode of the battery 11, its drain is connected to the drain of charge control transistor 13, and its gate is connected to the protection IC 14.

The charge control transistor 13 includes an n channel MOS field-effect transistor. In the charge control transistor 13, its source is connected to a terminal T2, its drain is connected to the drain of the discharge control transistor 12, and its gate is connected to the protection IC 14.

The protection IC 14 is connected to the junction point between the resistor R1 and the capacitor C1, the gate of the discharge control transistor 12 and the gate of the charge control transistor 13. Furthermore, the protection IC 14 is also connected to the terminal T2 via the resistor R2. The protection IC 14 detects overcharge, over-discharge, and overcurrent, and controls the discharge control transistor 12 and the charge control transistor 13.

FIG. 6 is graph for describing operations of the conventional battery. In the graph of FIG. 6, the horizontal axis indicates the output voltage of the battery 11, and the vertical axis indicates the voltage between the terminal T1 and the terminal T2. Furthermore, “V41” indicates over-discharge detection voltage, and “V42” indicates over-discharge return voltage.

An over-discharge state occurs when the voltage of the battery 11 becomes less than the over-discharge detection voltage V41. When the voltage of the battery 11 becomes greater than the over-discharge return voltage V42 after the protection IC 14 reaches an over-discharge protection state, the protection IC 14 switches out of the over-discharge protection state and turns on the over-discharge control transistor 12.

The charger 3 is connected between the terminal T1 and the terminal T2. The charger 3 detects over-discharge or overcharge of the battery 11 in accordance with the voltage between the terminals T1, T2 and starts/stops, respectively charging the battery 11.

In the conventional battery pack 1, even in a case where the voltage of the battery 11 is actually greater than the over-discharge return voltage V42, the voltage between the terminal T1 and the terminal T2 is decreased when the protection IC 14 reaches an over-discharge state due to forward direction voltage Vf of a parasitic diode D12 of the over-discharge control transistor 12. Thus, the charger 2 stops charging when the voltage between the terminal T1 and the terminal T2 becomes equal to or less than the over-discharge return voltage. As a result, charging cannot be sufficiently performed. That is, in the conventional battery pack 1, the over-discharge return can only be performed in the range [symbol] V10 shown in FIG. 6.

### SUMMARY OF THE INVENTION

It is a general object of the present invention to provide a battery protection method and a battery protection circuit that substantially obviates one or more of the problems caused by the limitations and disadvantages of the related art.

Features and advantages of the present invention will be set forth in the description which follows, and in part will become apparent from the description and the accompanying drawings, or may be learned by practice of the invention according to the teachings provided in the description. Objects as well as other features and advantages of the present invention will be realized and attained by a battery protection method and a battery protection circuit particularly pointed out in the specification in such full, clear, concise, and exact terms as to enable a person having ordinary skill in the art to practice the invention.

To achieve these and other advantages and in accordance with the purpose of the invention, as embodied and broadly described herein, an embodiment of the present invention provides a battery protection method for protecting a battery from an over-discharge state by switching off a switching element provided between the battery and a load in accordance with the voltage of the battery, the method including the steps of: detecting application of a charging voltage; and arranging a chargeable state for the battery by switching on the switching element when the charging voltage is applied.

In the battery protection method according to an embodiment of the present invention, the detection of the application of the charging voltage may include detection of a connection to a charger.

Furthermore, an embodiment of the present invention provides a battery protection circuit for protecting a battery from an over-discharge state by switching off a switching element provided between the battery and a load in accordance with the voltage of the battery, the battery protection circuit including: a charge voltage detection circuit part for detecting application of a charging voltage; and a control circuit part for arranging a chargeable state for the battery by switching on the switching element when the charging voltage is applied.

In the battery protection circuit according to an embodiment of the present invention, the detection of the application of the charging voltage may include detection of a connection to a charger.

Other objects and further features of the present invention will be apparent from the following detailed description when read in conjunction with the accompanying drawings.

### BRIEF DESCRIPTION OF THE DRAWINGS

FIG. 1 is a circuit diagram of a battery pack including a battery according to an embodiment of the present invention;

FIG. 2 is a circuit diagram of a protection IC according to an embodiment of the present invention;

FIG. 3 is a flowchart of an operation of a control circuit according to an embodiment of the present invention;

FIG. 4 is a graph for describing operations of a battery according to an embodiment of the present invention;

FIG. 5 is a circuit diagram of a conventional battery pack; and

FIG. 6 is a graph for describing operations of a conventional battery.

### DESCRIPTION OF THE PREFERRED EMBODIMENTS

In the following, embodiments of the present invention are described with reference to the accompanying drawings.

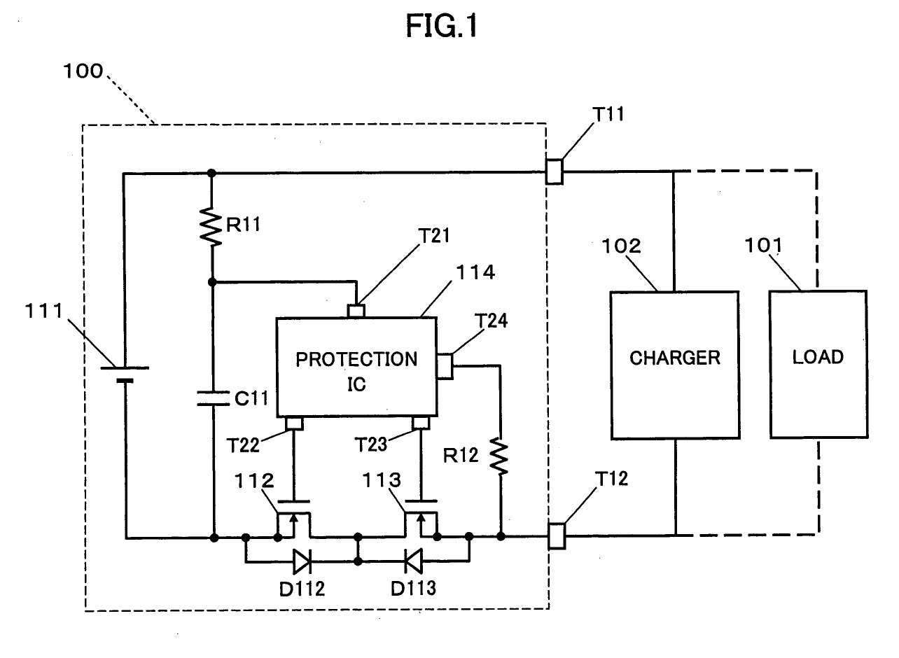

FIG. 1 is a block diagram showing a battery pack 100 according to an embodiment of the present invention.

In this embodiment, the battery pack 100 is mounted on, for example, a mobile phone serving as its power source. The battery pack 100 includes a battery 111, a discharge control transistor 112, a charge control transistor 113, a protection IC 114, resistors R11, R12, and a capacitor C11.

The battery 111 includes, for example, a lithium ion battery having an electric chargable/dischargable configuration. In the battery 111, the positive electrode is connected to a terminal T11 and the negative electrode is connected to the source of the discharge control transistor 112.

The discharge control transistor 112 includes an n channel MOS field-effect transistor. In the discharge control transistor 112, its source is connected to the negative electrode of the battery 111, its drain is connected to the drain of charge control transistor 113, and its gate is connected to a terminal T22 of the protection IC 114.

The charge control transistor 113 includes an n channel MOS field-effect transistor. In the charge control transistor 113, its source is connected to a terminal T12, its drain is connected to the drain of the discharge control transistor 112, and its gate is connected to a terminal T23 of the protection IC 114.

In the protection IC 114, the terminal T21 is connected to the junction point between the resistor R11 and the capacitor C11, the terminal T22 is connected to the gate of the discharge control transistor 112, the gate of the terminal T23 is connected to the charge control transistor 113, and the terminal T24 is connected to the terminal T12 via the resistor R12. Accordingly, the protection IC 114 detects overcharge and over-discharge according to the voltage of the terminal T21 and detects overcurrent according to the current flowing at the terminal T24. In accordance with the detection results, the protection IC 114 controls the discharge control transistor 112 and the charge control transistor 113 by controlling the voltage of the terminals T22, T23, respectively.

One end of the resistor R11 is connected to the positive electrode of the battery 111 and the other end of the resistor R11 is connected to the terminal T21. Thereby, power is supplied to the terminal T21 whereby the voltage of the battery is lowered. One end of the capacitor C11 is connected to the terminal T21 and the other end of the capacitor C11 is connected to the negative electrode of the capacitor C11. Thereby, the voltage of the terminal T21 is stabilized.

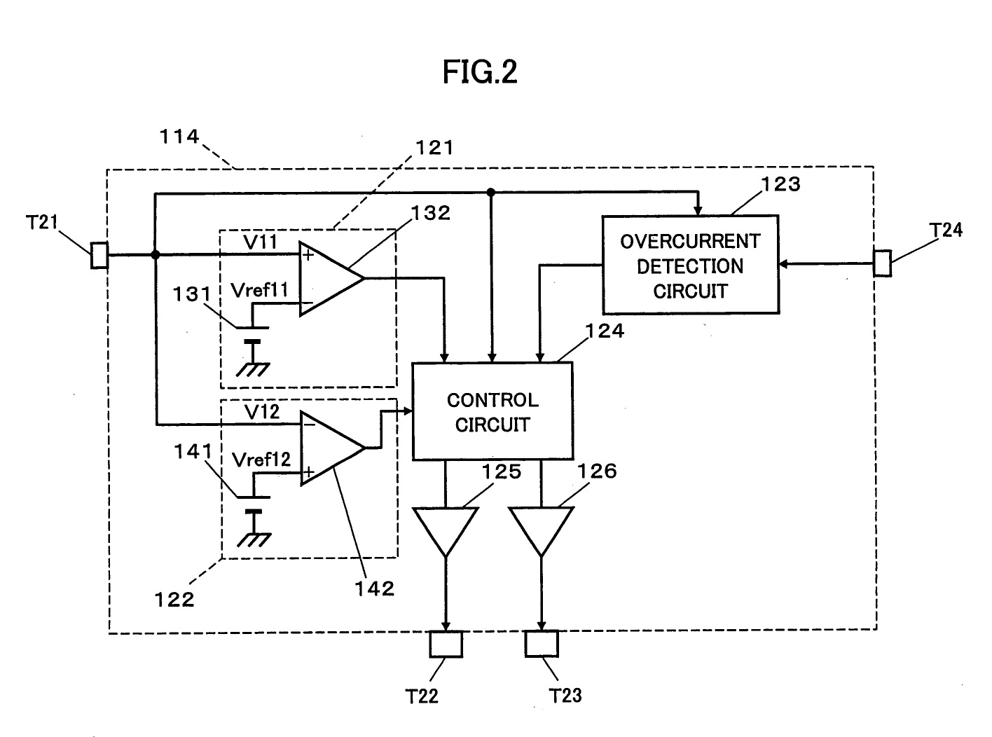

FIG. 2 is a circuit diagram showing an exemplary configuration of the protection IC 114 according to an embodiment of the present invention.

The protection IC 114 includes a overcharge detection circuit 121, an over-discharge detection circuit 122, an overcurrent detection circuit 123, a control circuit 124, and drivers 125, 126.

The overcharge detection circuit 121 includes a reference voltage source 131 and a comparator 132. The reference voltage source 131 generates a reference voltage Vref11. The reference voltage Vref11 generated by the reference voltage source 131 is supplied to the inverting input terminal of the comparator 132. The non-inverting terminal of the comparator 132 is connected to the terminal T21.

When the voltage V11 of the terminal T21 is less than the reference voltage Vref11, the output of the comparator 132 is a low level and the battery 111 reaches an overcharge state. When the voltage V11 of the terminal T21 is greater than the reference voltage Vref11, the output of the comparator 132 is a high level. The output of the comparator 132 is supplied to the control circuit 124.

The over-discharge detection circuit 122 includes a reference voltage source 141 and a comparator 142. The reference voltage source 141 generates a reference voltage Vref12. The reference voltage Vref12 generated by the reference voltage source 141 is supplied to the non-inverting input terminal of the comparator 142. The non-inverting input terminal of the comparator 142 is connected to the terminal T21.

When the voltage V12 of the terminal T21 is greater than the reference voltage Vref12, the output of the comparator 142 is a low level and the battery 111 reaches an over-discharge state. When the voltage V12 of the terminal T21 is less than the reference voltage Vref12, the output of the comparator 142 is a high level. The output of the comparator 142 is supplied to the control circuit 124.

The overcurrent detection circuit 123 detects the current flowing in the terminal T24. When the current flowing in the terminal T24 is less than a predetermined value, the output of the overcurrent detection circuit 123 is a low level. In the case of an overcurrent state, the current flowing in the terminal T24 becomes greater than the predetermined value. When the current flowing in the terminal T24 is greater than the predetermined value, the output of the overcurrent detection circuit 123 is a high level. The output of the overcurrent detection circuit 123 is supplied to the control circuit 124.

In a case where the battery 111 is in an overcharge state and the output of the overcharge detection circuit 121 is a high level, the control circuit 124 drives a driver 126 such that the voltage of the terminal T24 becomes a low level. By setting the voltage of the terminal T24 to a low level, the charge control transistor 113 is turned off. By turning off the charge control transistor 113, the connection between the battery 111 and the terminal T12 becomes disconnected and the negative electrode of the battery 111 reaches an open state. Thereby, charging the battery 111 is stopped.

Furthermore, in a case where the battery 111 is in an over-discharge state and the output of the over-discharge detection circuit 122 is a high level, the control circuit 124 drives a driver 125 such that the voltage of the terminal T23 becomes a low level. By setting the voltage of the terminal T23 to a low level, the discharge control transistor 112 is turned off. By turning off the discharge control transistor 112, the connection between the battery 111 and the terminal T12 is disconnected and the negative electrode of the battery becomes an open state. Thereby, charging the battery 111 is stopped.

Furthermore, in a case where an overcurrent state occurs and the output of the overcurrent detection circuit 123 is a high level, the control circuit 124 drives the driver 125 or the driver 126 such that the voltage of the terminal T23 or the voltage of the terminal T24 becomes a low level. By setting the voltage of the terminal T23 or the voltage of the terminal T24 to a low level, the discharge control transistor 112 or the charge control transistor 113 is turned off. By turning off the discharge control transistor 112 or the charge control transistor 113, the connection between the battery 111 and the terminal T12 is disconnected and the negative electrode of the battery becomes an open state. Thereby, the charging of the battery 111 is stopped.

Next, the operation (action) of the control circuit 124 is described in a case where charging voltage is applied.

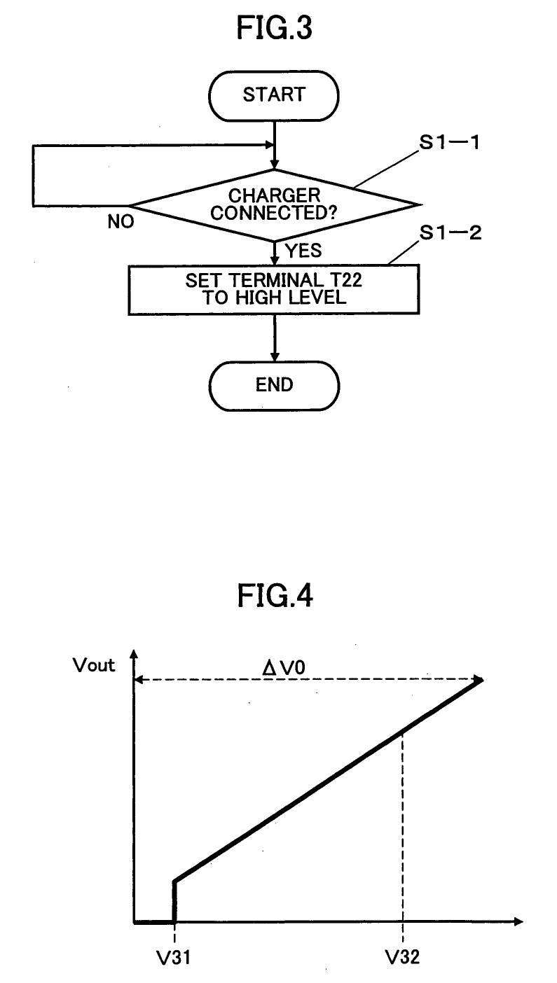

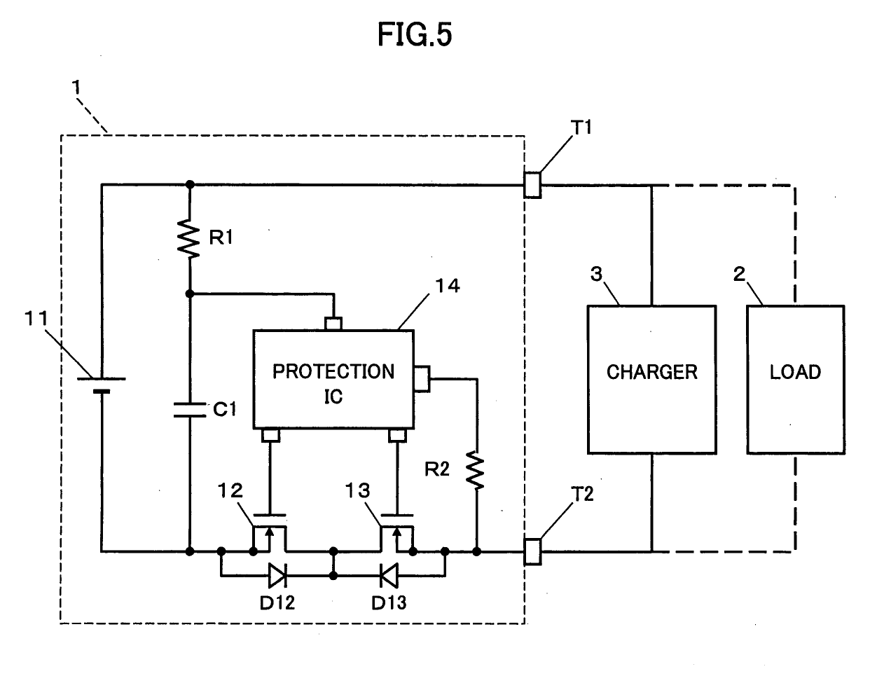

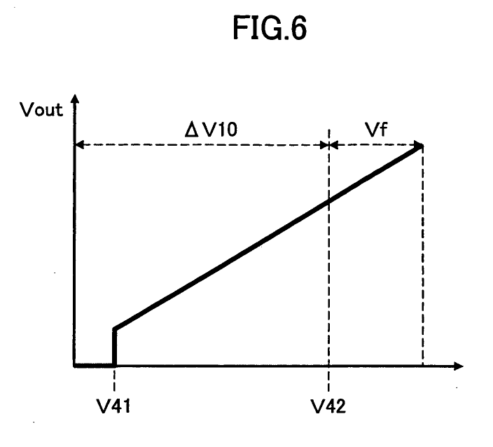

FIG. 3 is a flowchart of the operation (action) of the control circuit 124 according to an embodiment of the present invention.

In Step S1-1 of FIG. 3, the control circuit 124 detects the applying of charging voltage between the terminal T11 and the terminal T12 (connection with the charger). When the applying of charging voltage is detected (Yes in Step S1-1), the voltage of the terminal T22 is compulsorily set to a high level in Step S1-2. When the voltage of the terminal T22 is compulsorily set to a high level in Step S1-2, the discharge control transistor 112 is compulsorily turned on. If the battery 111 is not in an overcharge state, the charge control transistor 113 is also turned on. Accordingly, the battery 111 is connected to the charger via the terminal T11 and the terminal T12.

By connecting the battery 111 to the charger via the terminal T11 and the terminal T12, an over-discharge state of the battery 111 can be detected. In this state, since the discharge control transistor 112 is switched on, the battery 111 is connected to the terminals T11 and T12 without passing through the parasitic diode D112 of the discharge control transistor 112. Accordingly, the charger can precisely detect the voltage of the battery 111 and perform charging.

For example, in a case where the battery 111 is connected to the terminals T11 and T12 via the parasitic diode D112, the voltage between the terminal T11 and the terminal T12 is a voltage obtained by subtracting the forward direction voltage Vf of the parasitic diode D112 from the voltage of the battery 111. Therefore, the battery 111 is determined as having a voltage lower than the actual voltage of the battery 111. As a result, the battery 111 is determined to be in an over-discharge state even though the voltage of the battery 111 only is not a voltage of the over-discharge state.

Therefore, according to an embodiment of the present invention, in a case where the charger is connected to the battery 111, first, the discharge control transistor 112 is compulsorily turned on, and then, the voltage of the battery 111 is applied to the terminals T11 and T12 without the application of the forward direction voltage Vf of the parasitic diode D112 of the discharge control transistor 112. Accordingly, the over-discharge state of the battery 111 can be positively detected.

FIG. 4 is a graph for describing operations of the battery 111 according to an embodiment of the present invention. In the graph of FIG. 4, the horizontal axis indicates the output voltage of the battery 111, and the vertical axis indicates the voltage between the terminal T11 and the terminal T12. Furthermore, “V31” indicates over-discharge detection voltage, and “V32” indicates over-discharge return voltage.

The over-discharge state occurs when the voltage of the battery 111 becomes less than the over-discharge detection voltage V31. When the voltage of the battery becomes greater than the over-discharge return voltage V32 after the protection IC 114 reaches an over-discharge protection state, the protection IC 114 returns from the over-discharge protection state and it becomes possible for the charger 102 to charge the battery 111. In this state, according to an embodiment of the present invention, when the charger 102 is connected between the terminal T11 and the terminal T12, the protection IC 114 compulsorily returns from the over-discharge protection state without relying on the voltage of the battery 111.

Therefore, the protection IC 114 can return from the over-discharge state when the range of the voltage of the battery 111 is [symbol] V0 as shown in FIG. 4. Since the discharge control transistor 112 is turned on when the protection IC 114 returns from the over-discharge protection state, the battery 111 is connected to the charger 102 without passing through the parasitic diode D112 of the discharge control transistor 112. Thereby, voltage of the battery 111 is applied to the charger 102 without attenuation of the forward direction voltage Vf of the parasitic diode D112. Hence, the charger 102 can precisely detect the voltage of the battery 111 and determine whether the battery 111 is in an over-discharge state, to thereby start/stop charging.

Accordingly, charging can be performed on a battery 111 having a low voltage but not being in an over-discharge state.

Further, the present invention is not limited to these embodiments, but variations and modifications may be made without departing from the scope of the present invention.

The present application is based on Japanese Priority Application No. 2005-156375 filed on May 27, 2005, with the Japanese Patent Office, the entire contents of which are hereby incorporated by reference.

What is claimed is:

1. A battery protection method for protecting a battery from an over-discharge state by switching off a switching element provided between the battery and a load in accordance with the voltage of the battery, the method comprising the steps of:
detecting application of a charging voltage; and
arranging a chargeable state for the battery by switching on the switching element when the application of the charging voltage is detected.

2. The battery protection method as claimed in claim 1, wherein the detection of the application of the charging voltage includes detection of a connection to a charger.

3. A battery protection circuit for protecting a battery from an over-discharge state by switching off a switching element provided between the battery and a load in accordance with the voltage of the battery, the battery protection circuit comprising:
a charge voltage detection circuit part for detecting application of a charging voltage; and
a control circuit part for arranging a chargeable state for the battery by switching on the switching element when the application of the charging voltage is detected by the charge voltage detection circuit part.

4. The battery protection circuit as claimed in claim 3, wherein the detection of the application of the charging voltage includes detection of a connection to a charger.
